(19) United States
(12) Patent Application Publication
(10) Pub. No.: US 2023/0378550 A1
(43) Pub. Date: Nov. 23, 2023

(54) BATTERY MANAGEMENT SYSTEM AND BATTERY MANAGEMENT METHOD

(71) Applicant: ASUSTeK COMPUTER INC., Taipei City (TW)

(72) Inventor: Ke-Jen Hung, Taipei City (TW)

(73) Assignee: ASUSTeK COMPUTER INC., Taipei City (TW)

(21) Appl. No.: 17/973,544

(22) Filed: Oct. 26, 2022

(30) Foreign Application Priority Data
May 20, 2022 (CN) 202210550777.X

(51) Int. Cl. H01M 10/42; H02J 7/00; H01M 10/48; G06F 1/26; G01R 31/388

(52) U.S. Cl. CPC H01M 10/425; H02J 7/0048; H02J 7/00712; H02J 7/0013; H01M 10/482; G06F 1/263; G01R 31/388; H01M 2010/4271; H01M 2220/30

(57) ABSTRACT

A battery management system and a battery management method are provided. The battery management system includes a switching circuit, a switching circuit controller, a communication interface, a processor, and a timer. The switching circuit is coupled to the switching circuit controller. The communication interface is coupled to a system circuit. The processor is coupled to the switching circuit controller and the communication interface. The timer is coupled to the processor. In response to the processor determining that the system circuit stops communicating with the communication interface, the processor controls the timer to accumulate a continuous downtime of communication. In response to the processor determining that the continuous downtime of communication is greater than a default time threshold, the processor controls the switching circuit controller to cut off the switching circuit.

### CROSS-REFERENCE TO RELATED APPLICATION

This application claims the priority benefit of China application serial no. 202210550777.X, filed on May 20, 2022. The entirety of the above-mentioned patent application is hereby incorporated by reference herein and made a part of this specification.

### BACKGROUND

### Technical Field

The disclosure relates to a battery and a management method thereof, and particularly relates to a battery management system and a battery management method that prevent battery damage due to long-term storage.

### Description of Related Art

Generally speaking, a computer such as a notebook computer or a tablet computer includes a battery. The battery supplies electricity to a system circuit of the computer to perform operations. When the user does not use the computer for a long time, the computer is shut down and is in a storage state for a long time. However, during this period, the leakage current generated by the system circuit consumes the electricity of the battery, resulting in the battery's voltage being too low, resulting in swelling and damage.

### SUMMARY

The disclosure provides a battery management system and a battery management method that effectively prevent battery damage when an electronic device is in a non-working mode for a long time.

The battery management system of the disclosure manages a switching circuit between a battery module and a system circuit in an electronic device. The battery management system includes a switching circuit, a switching circuit controller, a communication interface, a processor, and a timer. The switching circuit controller is coupled to the switching circuit. The communication interface is coupled to a system circuit. The processor is coupled to the switching circuit controller and the communication interface. The timer is coupled to the processor. In response to the processor determining that the system circuit stops communicating with the communication interface, the processor controls the timer to accumulate a continuous downtime of communication. In response to the processor determining that the continuous downtime of communication is greater than a default time threshold, the processor controls the switching circuit controller to cut off the switching circuit.

The battery management method of the disclosure manages a switching circuit between a battery module and a system circuit in an electronic device. The battery management method includes: controlling a timer to accumulate a continuous downtime of communication in response to determining that the system circuit stops communicating with a communication interface; and controlling a switching circuit controller to cut off the switching circuit in response to determining that the continuous downtime of communication is greater than a default time threshold.

Based on the above, the battery management system and the battery management method of the disclosure monitor the continuous downtime of communication between the communication interface and the system circuit and cut off the switching circuit when the continuous downtime of communication is long enough. In this way, the battery management system and the battery management method block the leakage current of the system circuit that consumes the electricity of the battery that causes damage to the battery module.

In order to make the above-mentioned features and advantages of the disclosure comprehensible, embodiments accompanied with drawings are described in detail below.

### BRIEF DESCRIPTION OF THE DRAWINGS

FIG. 1 is a block schematic view of a battery management system according to an embodiment of the disclosure.

FIG. 2 is a flowchart of a battery management method according to an embodiment of the disclosure.

FIG. 3 is a block schematic view of a battery management system according to another embodiment of the disclosure.

FIG. 4 is a flowchart of a battery management method according to another embodiment of the disclosure.

### DESCRIPTION OF THE EMBODIMENTS

Some embodiments of the disclosure accompanied with the drawings will now be described in detail. In the reference numerals recited in description below, the same reference numerals shown in different drawings are regarded as the same or similar elements. These embodiments are only a part of the disclosure and do not disclose all possible implementations of the disclosure. More precisely, the embodiments are merely examples of the device and the method.

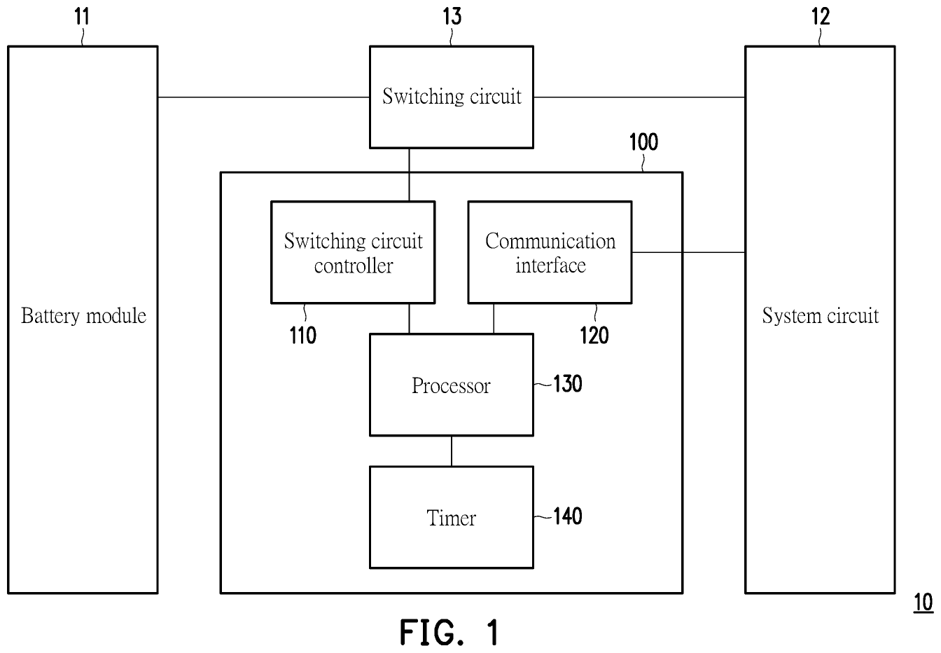

FIG. 1 is a block schematic view of a battery management system according to an embodiment of the disclosure. Referring to FIG. 1, a battery management system 100 is applied in an electronic device 10. In this embodiment, the electronic device 10 is, for example, a notebook computer or a computer device, etc. The aforementioned computer device may be, for example, a cell phone, a tablet computer, etc. The electronic device 10 includes a battery module 11 and a system circuit 12. The battery module 11 may be coupled to the system circuit 12 through a switching circuit 13. In this embodiment, the switching circuit 13 refers to a circuit through which the electricity consumption of the system circuit 12 flows. In some embodiments, the battery module 11 may also be coupled to the system circuit 12 through an electricity supply circuit (same as the switching circuit) to provide electricity to the system circuit 12.

In this embodiment, the battery module 11 is, for example, a storage battery module. The battery module 11 includes a multi-series and multi-parallel multi-cell lithium battery. In this embodiment, the system circuit 12 is, for example, a circuit that realizes the operating system of the electronic device 10. The system circuit 12 includes a computer main board device. In some embodiments, the battery management system 100 may be integrated into the electronic device 10 together with the battery module 11 and the system circuit 12.

In this embodiment, the battery management system 100 is coupled to the system circuit 12 and the battery module 11 through the switching circuit 13 between the battery module 11 and the system circuit 12. In this embodiment, the battery management system 100 may manage the switching circuit 13 to cut off the switching circuit 13 under certain conditions. That is to say, the battery management system 100 may control (e.g., block) the current to flow between the battery module 11 and the system circuit 12. In this embodiment, the battery management system 100 includes a switching circuit controller 110, a communication interface 120, a processor 130, and a timer 140.

In this embodiment, the switching circuit controller 110 is coupled to the switching circuit 13. The switching circuit controller 110 may cut off the switching circuit 13 to stop the flow of the leakage current. In some embodiments, switching circuit controller 110 may turned on switching circuit 13 to transfer electricity between battery module 11 and system circuit 12.

In this embodiment, the communication interface 120 is coupled to the system circuit 12. When the system circuit 12 is working (e.g., the system circuit 12 is in the working mode), The communication interface 120 may send or receive communication information to or from the system circuit 12 to establish communication with the system circuit 12. In this embodiment, the communication interface 120 is, for example, a universal serial bus (USB), a fire wire, Ethernet, a universal asynchronous receiver/transmitter (UART), a serial peripheral interface bus (SPI), and other connection interfaces.

In this embodiment, the processor 130 is coupled to the switching circuit controller 110, the communication interface 120, and the timer 140. The processor 130 may receive the communication information received by the communication interface 120 and the time information accumulated by the timer 140. The processor 130 may also control at least one of the switching circuit controller 110, the communication interface 120, and the timer 140 according to the communication information and the time information. In this embodiment, the processor 130 is, for example, a central processing unit (CPU), or a programmable microprocessor of common usage or specific usage, a digital signal processor (DSP), programmable controller, a application specific integrated circuits (ASIC), a programmable logic device (PLD), or other similar apparatus or the combinations thereof, which may load and execute computer programs.

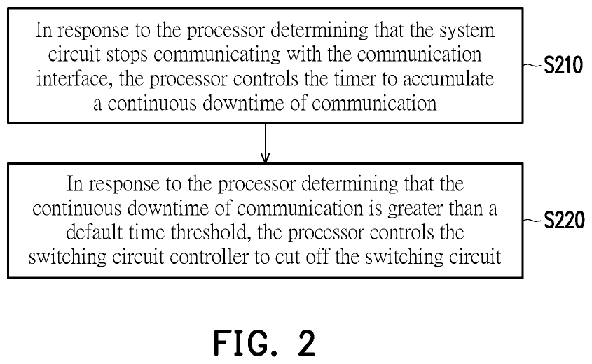

FIG. 2 is a flowchart of a battery management method according to an embodiment of the disclosure. Referring to FIG. 1 and FIG. 2, the battery management system 100 may perform the following steps S210 to S220 to manage the switching circuit 13 between the battery module 11 and the system circuit 12. In this embodiment, steps S210 to S220 may be applied to the following exemplary cases.

In this embodiment, when the electronic device 10 is in a non-working mode such as shutdown, sleep mode, or hibernation mode, the system circuit 12 stops working. In this embodiment, when the system circuit 12 stops working, the system circuit 12 stops sending or receiving communication information to or from the communication interface 120 to stop communication with the communication interface 120. In some embodiments, when the system circuit 12 stops working, the system circuit 12 sends communication information commanded to stop communication to the communication interface 120 to stop communication with the communication interface 120. At this time, the processor 130 may determine whether the communication between the system circuit 12 and the communication interface 120 is stopped according to the communication information of the communication interface 120.

In step S210, when the processor 130 determines that the system circuit 12 stops communicating with the communication interface 120, the processor 130 controls the timer 140 to accumulate a continuous downtime of communication.

In this embodiment, when the result determined by the processor 130 indicates that the communication between the system circuit 12 and the communication interface 120 is stopped, the processor 130 drives the timer 140 to start timing. It should be noted that the timer 140 starts to accumulate time from when the system circuit 12 and the communication interface 120 stop communicating. Therefore, the time counted by the timer 140 is the time during which the communication between the system circuit 12 and the communication interface 120 is continuously stopped (i.e., the continuous downtime of communication).

In step S220, when the processor 130 determines the continuous downtime of communication is greater than a default time threshold, the processor 130 controls the switching circuit controller 110 to cut off the switching circuit 13.

In this embodiment, when the continuous downtime of communication is greater than a default time threshold (e.g., 14 days), it means that the electronic device 10 is or will be in a non-working mode such as shutdown, sleep mode, or hibernation mode for a long time. At this time, the processor 130 drives the switching circuit controller 110 to cut off the switching circuit 13. That is to say, when the continuous downtime of communication is long enough to indicate that the electronic device 10 is in the non-working mode for a long time, the switching circuit controller 110 cuts off the switching circuit 13 to block the leakage current flow between in the system circuit 12 and the battery module 11.

In this embodiment, when the continuous downtime of communication is not greater than a default time threshold (e.g., 14 days), it means that the electronic device 10 is not or will not be in a non-working mode such as shutdown, sleep mode, or hibernation mode for a long time. At this time, the timer 140 continues the accumulation of the continuous downtime of communication. That is to say, when the continuous downtime of communication is not long enough, indicating that the electronic device 10 is not in the non-working mode for a long time, the battery management system 100 continues to execute step S210.

It is worth mentioning that the battery management system 100 may determine whether the system circuit 12 is in the non-working mode for a long time according to the continuous downtime of communication accumulated between the communication interface 120 and the system circuit 12 when the communication stops. When the continuous downtime of communication is long enough, it means that the system circuit 12 is in the non-working mode for a long time. At this time, the battery management system 100 may cut off the switching circuit 13 to prevent the battery module 11 from being damaged due to leakage current, which may also prevent the battery module 11 from losing electricity, thereby prolonging the usage lifetime of the battery module 11.

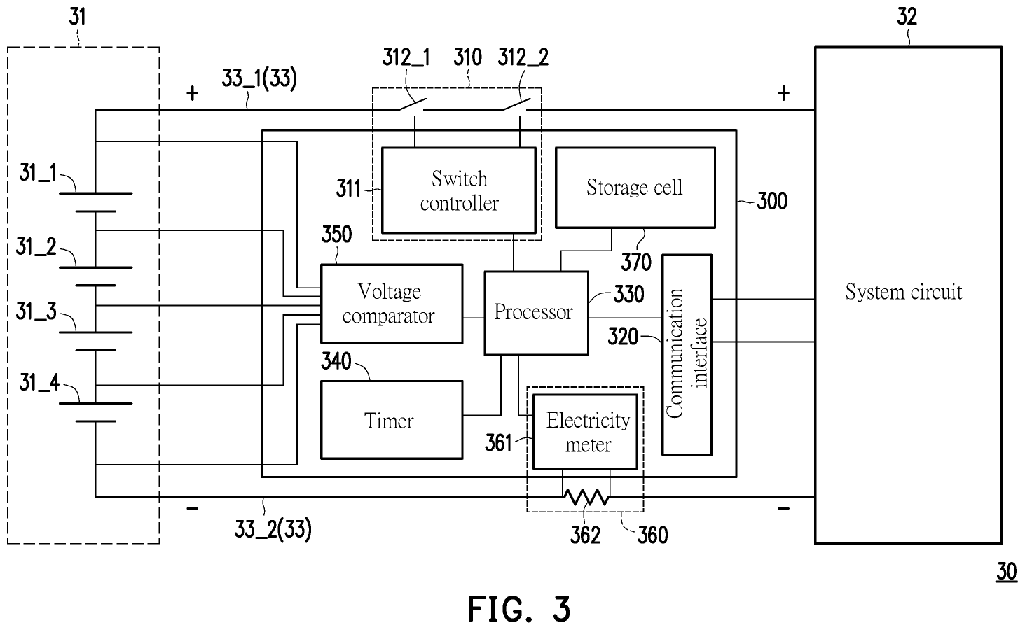

FIG. 3 is a block schematic view of a battery management system according to another embodiment of the disclosure. Referring to FIG. 3, the battery management system 300 manages a switching circuit 33 between a battery module 31 and a system circuit 32 in an electronic device 30. The switching circuit controller 310, the communication interface 320, the processor 330, and the timer 340 included in the battery management system 300 may be deduced by referring to the relevant description of the battery management system 100, and thus will not be repeated herein.

In this embodiment, the switching circuit 33 includes a first circuit 33_1 and a second circuit 33_2. In this embodiment, the first circuit 33_1 is coupled between a positive electrode of the battery module 31 and a positive electrode of the system circuit 32. The second circuit 33_2 is coupled between a negative electrode of the battery module 31 and a negative electrode of the system circuit 32. The configuration of the first circuit 33_1 and the second circuit 33_2 and the coupling relationship of the polarities are only examples, which are not limited thereto.

In this embodiment, the switching circuit controller 310 is disposed on the first circuit 33_1. The switching circuit controller 310 includes a switch controller 311 and switches 312_1 to 312_2. The switch controller 311 is coupled to the processor 130 and the switches 312_1 to 312_2. The switch controller 311 is controlled by the processor 130 and controls the switches 312_1 to 312_2 according to the commands from the processor 130 to turn on or cut off the switches 312_1 to 312_2. In this embodiment, the switch controller 311 is, for example, a programmable microprocessor of common usage or specific usage, a digital signal processor (DSP), programmable controller, a application specific integrated circuits (ASIC), a programmable logic device (PLD), or other similar apparatus or the combinations thereof, which may load and execute computer programs.

In this embodiment, the switches 312_1 to 312_2 are disposed on the first circuit 33_1. The switches 312_1 to 312_2 is controlled by the switch controller 311 to be turned on or turned off to further turn on or cut off the first circuit 33_1. The number of switches 312_1 to 312_2 is only an example, which is not limited thereto.

In this embodiment, the battery management system 300 further includes a voltage comparator 350, an electricity counting circuit 360, and a storage cell 370. In this embodiment, the voltage comparator 350 is coupled to the processor 330 and the battery module 31. The voltage comparator 350 may detect the voltage of the battery module 31 to generate an open-circuit voltage (OCV) of the battery module 31. In this embodiment, the processor 330 may calculate the state of charge (SOC) of the battery module 31 according to the voltage of the battery module 31. For example, the processor 330 may search the lookup table according to the voltage of the battery module 31 to obtain a corresponding state of charge (i.e., the stored electricity in percentage) of the battery module 31.

Specifically, in this embodiment, the voltage comparator 350 is respectively coupled to two ends of the battery strings 31_1 to 31_4 of the battery module 31. The battery strings 31_1 to 31_4 is connected in series between the first circuit 33_1 and the second circuit 33_2. In this embodiment, the voltage comparator 350 may detect the voltage of each battery strings 31_1 to 31_4 to generate multiple voltages corresponding to the battery strings 31_1 to 31_4. In this embodiment, the processor 330 may respectively calculate corresponding states of charge according to the voltages of the battery strings 31_1 to 31_4. For example, the voltage comparator 350 detected the voltage on the two ends of the battery string 31_1 to obtain the voltage of the battery string 31_1. In this embodiment, the battery string 31_1 is made up of, for example, lithium ion (Li-ion) batteries connected in series, but the disclosure is not limited thereto. The battery strings 31_2 to 31_4 may be deduced by referring to the related description of the battery string 31_1, and thus will not be repeated herein.

It should be noted that the voltage detected by the voltage comparator 350 includes the voltage of the entire battery module 31 and the voltage of each of the battery strings 31_1 to 31_4. Therefore, the state of charge obtained by the processor 330 includes the state of charge of the entire battery module 31 and the state of charge of each of the battery strings 31_1 to 31_4.

In this embodiment, the electricity counting circuit 360 is disposed on the second circuit 33_2. The electricity counting circuit 360 is coupled to the processor 330, the battery module 31, and the system circuit 32. The electricity counting circuit 360 may detect the electricity of the battery module 31 to generate an electricity signal. In this embodiment, the processor 330 may determine a stored electricity of the battery module 31 according to the electricity signal.

Specifically, in this embodiment, the electricity counting circuit 360 includes an electricity meter 361 and a resistor 362. The resistor 362 is disposed on the second circuit 33_2. One end of the resistor 362 is coupled to the battery module 31, and the other end of the resistor 362 is coupled to the system circuit 32. The electricity meter 361 is coupled to two ends of the resistor 362 to measure the voltage or current of the two ends of the resistor 362. The electricity signal of the electricity meter 361 is positively related to the stored electricity of the battery module 31. It should be noted that the stored electricity obtained by the processor 330 includes the entire stored electricity of the battery module 31.

In this embodiment, the storage cell 370 is coupled to the processor 330. The storage cell 370 may store data on voltage and electricity as well as lookup tables. In this embodiment, the aforementioned lookup table is, for example, a battery voltage table, such as an open circuit voltage table (OCV table). In this embodiment, the storage cell 370 is, for example, a dynamic random access memory (DRAM), a flash memory, or a non-volatile random access memory (NVRAM), etc.

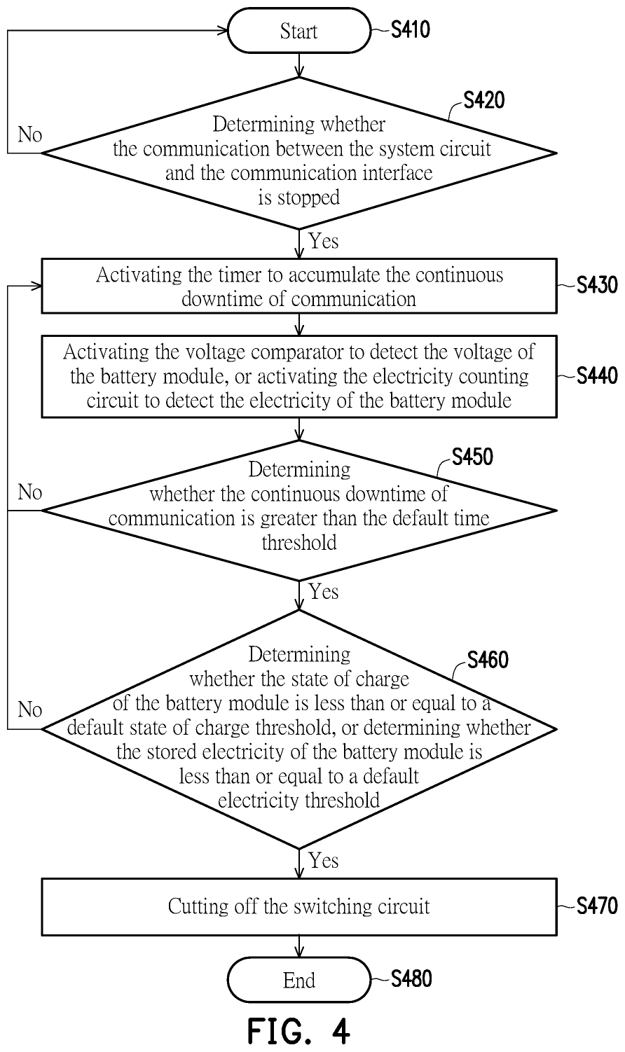

FIG. 4 is a flowchart of a battery management method according to another embodiment of the disclosure. Referring to FIG. 3 and FIG. 4, the battery management system 300 may perform the following steps S410 to S480 to manage the switching circuit 33 between the battery module 31 and the system circuit 32.

In step S410, the battery management system 300 starts to work.

In this embodiment, when the electronic device 30 is in a non-working mode such as shutdown, sleep mode, or hibernation mode, the system circuit 32 stops working and stops communicating with the communication interface 320.

In step S420, the processor 330 determines whether the communication between the system circuit 32 and the communication interface 320 is stopped according to the communication information of the communication interface 320.

If the result of step S420 is no, it means that the electronic device 30 has not entered the non-working mode and the battery management system 300 restarts execution from step S420.

If the result of step S420 is yes, it means that the electronic device 30 has entered the non-working mode, and the battery management system 300 executes step S430. In step S430, the processor 330 activates the timer 340, so that the timer 340 accumulates the continuous downtime of communication. It should be noted that the timer 340 starts to accumulate time from when the system circuit 32 and the communication interface 320 stop communicating. Therefore, the time counted by the timer 340 is the time during which the communication between the system circuit 32 and the communication interface 320 is continuously stopped (i.e., the continuous downtime of communication).

In step S440, the processor 330 activates the voltage comparator 350, and the voltage comparator 350 detects the voltage of the battery module 31. The processor 330 further calculates the state of charge of the battery module 31 according to the voltage detected by the voltage comparator 350. Alternatively, in step S440, the processor 330 activates the electricity counting circuit 360, and the electricity counting circuit 360 detects the electricity of the battery module 31 to generate an electricity signal. The processor 330 further obtains the electricity of the battery module 31 according to the electricity signal detected by the electricity counting circuit 360.

It should be noted that, in this embodiment, the processor 330 may select to activate either the voltage comparator 350 or the electricity counting circuit 360. In some embodiments, the processor 330 may activate the voltage comparator 350 and the electricity counting circuit 360 simultaneously, or one after the other.

In step S450, the processor 330 determines whether the continuous downtime of communication is greater than the default time threshold (e.g., 14 days) according to the continuous downtime of communication of the timer 340.

If the result of step S450 is no, it means that the continuous downtime of communication is not greater than the default time threshold. That is to say, if the electronic device 30 has not been in the non-working mode for a long time and the battery management system 300 restarts execution from step S420.

If the result of step S450 is yes, it means that the continuous downtime of communication is greater than the default time threshold. That is to say, if the electronic device 30 has been in the non-working mode for a long time and the battery management system 300 continues to execute step S460.

In step S460, when the continuous downtime of communication is greater than the default time threshold, the processor 330 determines whether the state of charge of the battery module 31 is less than or equal to a default state of charge threshold according to the voltage detected by the voltage comparator 350 to control the switching circuit controller 310 to cut off the switching circuit 33. Alternatively, in step S460, when the continuous downtime of communication is greater than the default time threshold, the processor 330 determines whether the stored electricity of the battery module 31 is less than or equal to a default electricity threshold according to the electricity signal detected by the electricity counting circuit 360 to control the switching circuit controller 310 to cut off the switching circuit 33.

It should be noted that, in this embodiment, the processor 330 may either determine whether the state of charge of the battery module 31 is within a default range according to the voltage detected by the voltage comparator 350, or whether the stored electricity of the battery module 31 is within a default range according to the electricity signal detected by the electricity counting circuit 360. In some embodiments, the processor 330 may either determine whether the state of charge and (or) the electricity of the battery module 31 is within a default range according to the voltage detected by the voltage comparator 350 and the electricity signal detected by the electricity counting circuit 360 simultaneously, or one after the other.

If the result of step S460 is no, it means that the state of charge of the battery module 31 is not less than or equal to the default state of charge threshold, or the stored electricity of the battery module 31 is not less than or equal to the default electricity threshold. That is to say, when the electronic device 30 is in the non-working mode for a long time, the electricity of the battery module 31 is too high and does not fall within a default stored voltage range and/or a default stored electricity range. At this time, the battery management system 300 restarts execution from step S430.

In this embodiment, the default stored voltage range or the default stored electricity range refers to the self-sustained stored voltage (corresponding to the state of charge, stored electricity) of the battery module 31 without supplying electricity to the system circuit 32 so as not to be damaged or consume excessive electricity.

For example, in this embodiment, the default stored voltage range or the default stored electricity range includes a state of charge greater than 50% (i.e., 50% SOC), a state of charge of fully charge capacity greater than 50%, a state of charge of the design capacity greater than 50%, and a state of charge of the remaining capacity greater than 50%. In this embodiment, the default state of charge threshold and the default electricity threshold are, for example, 50%.

If the result of step S460 is yes, it means that the state of charge of the battery module 31 is less than or equal to the default state of charge threshold, or the stored electricity of the battery module 31 is less than or equal to the default electricity threshold. That is to say, when the electronic device 30 is in the non-working mode for a long time, the electricity of the battery module 31 is already within a default stored voltage range and/or a default stored electricity range. At this time, the battery management system 300 continues to execute step S470.

In some embodiments, the processor 330 may calculate corresponding states of charge according to the voltages of the battery strings 31_1 to 31_4 detected by the voltage comparator 350. When the continuous downtime of communication is greater than the default time threshold, the processor 330 determines whether at least one of the states of charge is less than or equal to the default state of charge threshold according to the voltages detected by the voltage comparator 350 to control the switching circuit controller 310 to cut off the switching circuit 33. That is to say, the processor 330 determines whether the state of charge of each of the battery strings 31_1 to 31_4 is less than or equal to the default state of charge threshold. When the state of charge of any one of the battery strings 31_1 to 31_4 does not meet the result determined in step S460, the battery management system 300 restarts execution from step S430. When the state of charge of any one or each of the battery strings 31_1 to 31_4 complies with the result determined in step S460, the battery management system 300 continues to execute step S470.

In step S470, when the continuous downtime of communication is greater than the default time threshold and when the battery module 31 is already within a default stored voltage range or a default stored electricity range, the processor 330 controls the switching circuit controller 310 to cut off the first circuit 33_1 of the switching circuit 33 to block the leakage current flow between in the system circuit 32 and the battery module 31.

In step S480, the battery management system 300 ends the work.

To sum up, the battery management system and the battery management method of the disclosure monitor whether the communication between the communication interface and the system circuit stops and accumulate the continuous downtime of communication to automatically determine whether the system circuit is in the non-working mode for a long time. In addition, the battery management system and the battery management method may also cut off the switching circuit according to the aforementioned result to block the leakage current and prevent the battery module from being damaged. In some embodiments, the battery management system and the battery management method may further determine whether to cut off the switching circuit according to the current state of charge or electricity of the battery module, thereby saving the electricity and reserving the electricity to further extend the lifetime of the battery module.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A battery management system, managing a switching circuit between a battery module and a system circuit in an electronic device, comprising:
a switching circuit controller, coupled to the switching circuit;
a communication interface, coupled to the system circuit;
a processor, coupled to the switching circuit controller and the communication interface; and
a timer, coupled to the processor,
wherein in response to the processor determining that the system circuit stops communicating with the communication interface, the processor controls the timer to accumulate a continuous downtime of communication, and in response to the processor determining that the continuous downtime of communication is greater than a default time threshold, the processor controls the switching circuit controller to cut off the switching circuit.

2. The battery management system according to claim 1, wherein the switching circuit comprises a first circuit, and the first circuit is coupled between a positive electrode of the battery module and a positive electrode of the system circuit.

3. The battery management system according to claim 2, wherein the switching circuit controller controls a switching circuit on the first circuit.

4. The battery management system according to claim 2, further comprising:
an electricity counting circuit, coupled to the processor and the battery module and detecting an electricity of the battery module to generate an electricity signal,
wherein the processor determines a stored electricity of the battery module according to the electricity signal, and in response to the processor determining that the continuous downtime of communication is greater than the default time threshold, the processor further determines whether the stored electricity is less than or equal to a default electricity threshold to control the switching circuit controller to cut off the switching circuit.

5. The battery management system according to claim 4, wherein the electricity counting circuit is disposed on a second circuit of the switching circuit.

6. The battery management system according to claim 1, further comprising:
a voltage comparator, coupled to the processor and the battery module and detecting a voltage of the battery module,
wherein the processor calculates a state of charge of the battery module according to the voltage, and in response to the processor determining that the continuous downtime of communication is greater than the default time threshold, the processor further determines whether the state of charge is less than or equal to a default state of charge threshold to control the switching circuit controller to cut off the switching circuit.

7. The battery management system according to claim 6, further comprising:
a storage cell, coupled to the processor and storing a lookup table,
wherein the processor searches the lookup table according to the voltage to obtain a corresponding state of charge.

8. The battery management system according to claim 6, wherein the voltage comparator is respectively coupled to two ends of a plurality of battery strings of the battery module to generate a plurality of voltages corresponding to the battery strings, and the processor calculates a plurality of states of charge of the battery strings according to the voltages, and in response to the processor determining that the continuous downtime of communication is greater than the default time threshold, the processor further determines whether at least one of the states of charge is less than or equal to the default state of charge threshold to control the switching circuit controller to cut off the switching circuit.

9. The battery management system according to claim 1, wherein the electronic device is a notebook computer or a computer device, and the system circuit comprises a computer main board device.

10. The battery management system according to claim 1, wherein the battery module comprises a multi-series and multi-parallel multi-cell lithium battery.

11. A battery management method for managing a switching circuit between a battery module and a system circuit in an electronic device, comprising:
controlling a timer to accumulate a continuous downtime of communication in response to determining that the system circuit stops communicating with a communication interface; and
controlling a switching circuit controller to cut off the switching circuit in response to determining that the continuous downtime of communication is greater than a default time threshold.

12. The battery management method according to claim 11, wherein the switching circuit comprises a first circuit, and the first circuit is coupled between a positive electrode of the battery module and a positive electrode of the system circuit.

13. The battery management method according to claim 12, wherein the switching circuit is disposed on the first circuit.

14. The battery management method according to claim 12, further comprising:
detecting an electricity of the battery module through an electricity counting circuit;
determining a stored electricity of the battery module according to an electricity signal; and
further determining whether the stored electricity is less than or equal to a default electricity threshold to control the switching circuit controller to cut off the switching circuit in response to determining that the continuous downtime of communication is greater than the default time threshold.

15. The battery management method according to claim 14, wherein the electricity counting circuit is disposed on a second circuit of the switching circuit.

16. The battery management method according to claim 11, further comprising:
detecting a voltage of the battery module through a voltage comparator, and calculating a state of charge of the battery module according to the voltage detected; and
further determining whether the state of charge is less than or equal to a default state of charge threshold to control the switching circuit controller to cut off the switching circuit.

17. The battery management method according to claim 16, further comprising:
obtaining a plurality of voltages corresponding to a plurality of battery strings of the battery module through the voltage comparator, wherein the voltage comparator is respectively coupled to two ends of the battery strings;
calculating a plurality of states of charge of the battery strings according to the voltages; and
further determining whether at least one of the states of charge is less than or equal to the default state of charge threshold to control the switching circuit controller to cut off the switching circuit in response to determining that the continuous downtime of communication is greater than the default time threshold.

18. The battery management method according to claim 11, wherein the electronic device is a notebook computer or a computer device, and the system circuit comprises a computer main board device.

19. The battery management method according to claim 11, wherein the battery module comprises a multi-series and multi-parallel multi-cell lithium battery.
